(19) United States
(12) Patent Application Publication
(10) Pub. No.: US 2013/0284508 A1
(43) Pub. Date: Oct. 31, 2013

(54) PRINTED CIRCUIT BOARD

(71) Applicants: WEI-CHIEH CHOU, Tu-Cheng (TW); CHUN-JEN CHEN, Tu-Cheng (TW); DUEN-YI HO, Tu-Cheng (TW); TSUNG-SHENG HUANG, Tu-Cheng (TW); PO-CHUAN HSIEH, Tu-Cheng (TW); CHUN-NENG LIAO, Tu-Cheng (TW)

(72) Inventors: WEI-CHIEH CHOU, Tu-Cheng (TW); CHUN-JEN CHEN, Tu-Cheng (TW); DUEN-YI HO, Tu-Cheng (TW); TSUNG-SHENG HUANG, Tu-Cheng (TW); PO-CHUAN HSIEH, Tu-Cheng (TW); CHUN-NENG LIAO, Tu-Cheng (TW)

(73) Assignee: HON HAI PRECISION INDUSTRY CO., LTD., Tu-Cheng (TW)

(21) Appl. No.: 13/563,856

(22) Filed: Aug. 1, 2012

(30) Foreign Application Priority Data
Apr. 27, 2012 (TW) 101115066

(51) Int. Cl. H05K 1/11

(52) U.S. Cl. 174/266

(57) ABSTRACT

A printed circuit board (PCB) includes a power layer and a signal layer. A signal line is arranged on the signal layer. A power via extends through the power layer and the signal layer, and is electrically connected to the power layer and the signal layer. A number of through holes is defined in the PCB, through the power layer and the signal layer, and arranged between the signal line and the power via. The through holes are insulated from the power via. The inside wall of the power via is made of conductive material.

### BACKGROUND

1. Technical Field

The present disclosure relates to a printed circuit board (PCB).

2. Description of Related Art

At present, voltage converters are widely used in computers because they have high voltage converting efficiency. However, noise generated during voltage conversion will affect signal transmission quality of the PCB of the computer. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments.

FIG. 1 is a cross-sectional view of a printed circuit board (PCB) in accordance with an exemplary embodiment of the present disclosure, wherein the PCB includes a signal layer.

FIG. 2 is a plan view of the signal layer of FIG. 1.

FIG. 3 is an enlarged view of the circled portion III of FIG. 1.

FIG. 4 is a graph of comparing noise performance of the PCB of FIG. 1 with and without modification according to an embodiment.

### DETAILED DESCRIPTION

The disclosure, including the drawings, is illustrated by way of example and not by way of limitation. References to “an” or “one” embodiment in this disclosure are not necessarily to the same embodiment, and such references mean at least one.

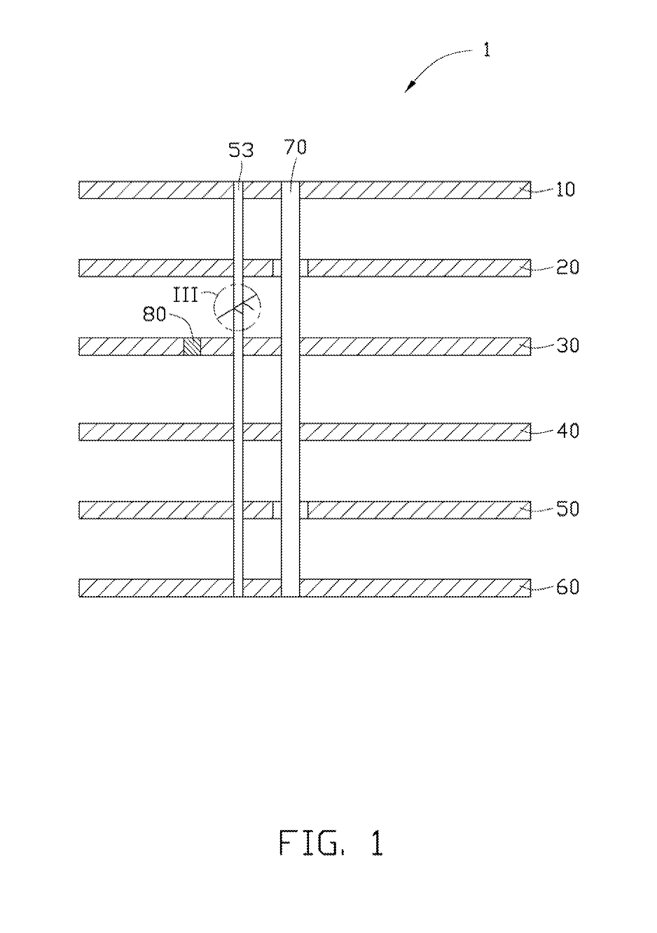

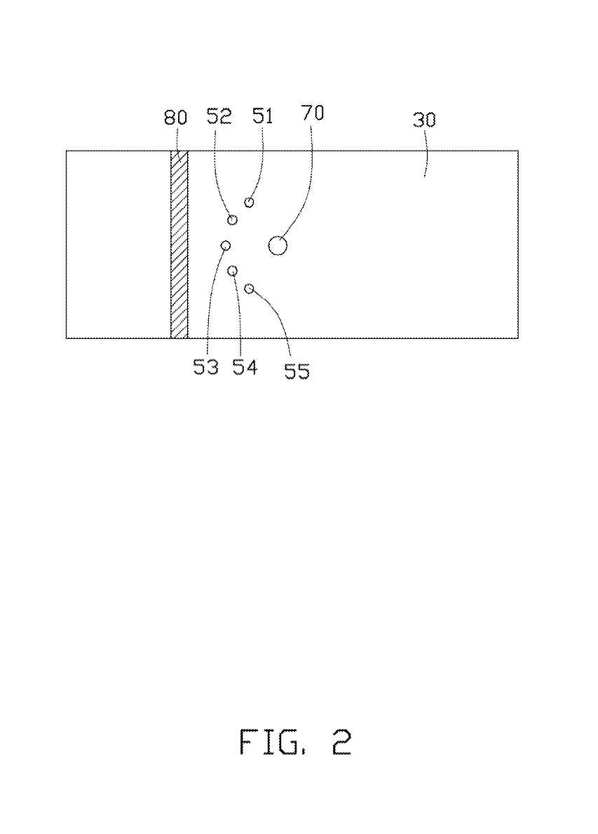

Referring to FIGS. 1 and 2, a printed circuit board (PCB) 1 in accordance with an exemplary embodiment includes a power layer 10, two ground layers 20 and 50, and three signal layers 30, 40, and 60. A signal line 80 is arranged on the signal layer 30. A power via 70 extends through the power layer 10, the ground layer 20, the signal layers 30 and 40, the ground layer 50, and the signal layer 60 in that order, and is electrically connected to the power layer 10 and the signal layers 30, 40, and 60. A plurality of through holes (such as five through holes 51-55) is defined in the PCB 1, through the power layer 10, the signal layers 30, 40, and 60, and the ground layers 20 and 50, and arranged between the signal line 80 and the power via 70. The inside wall of the power via 70 is made of conductive material, such as copper.

The power layer 10 provides voltages to the signal layers 30, 40, and 60 through the power via 70. The through holes 51-55 are arranged on an arc around the power via 70. In other embodiments, the number of the through holes and their arrangement are selected according to need.

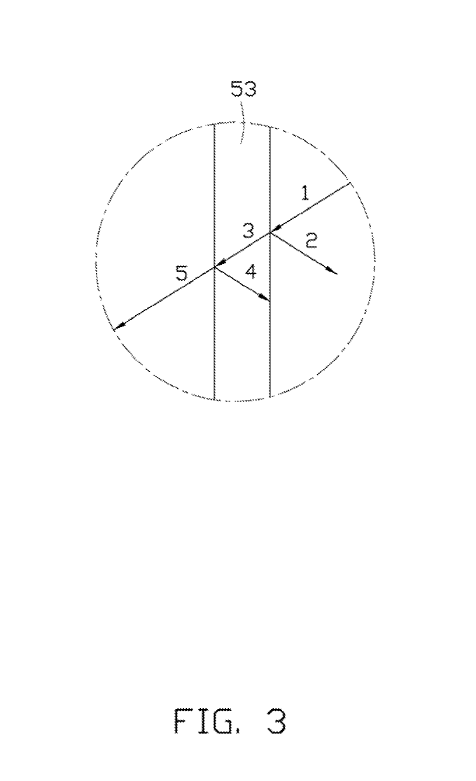

Referring to FIG. 3, the signal layer 30 is taken as an example. Before noise reaches the signal line 80, it is transmitted to the through holes 51-55 through the power via 70. In one embodiment, the through hole 53 is taken as an example. When noise enters the through hole 53 along a direction 1, a first part of the noise is reflected by an outside wall of the through hole 53 along a direction 2. A second part of the noise enters the through hole 53 along a direction 3. A portion of the second part of the noise is reflected by the inside wall of the through hole 53 along a direction 4, and the remaining portion of the second part of the noise is transmitted to the signal line 80 of the signal layer 30 along a direction 5. Namely, only a small part of the noise is transmitted to the signal line 80 of the signal layer 30 through the power via 70 and the through hole 53. Therefore, the noise transmitted to the signal line 80 is reduced, to improve quality of signal transmission.

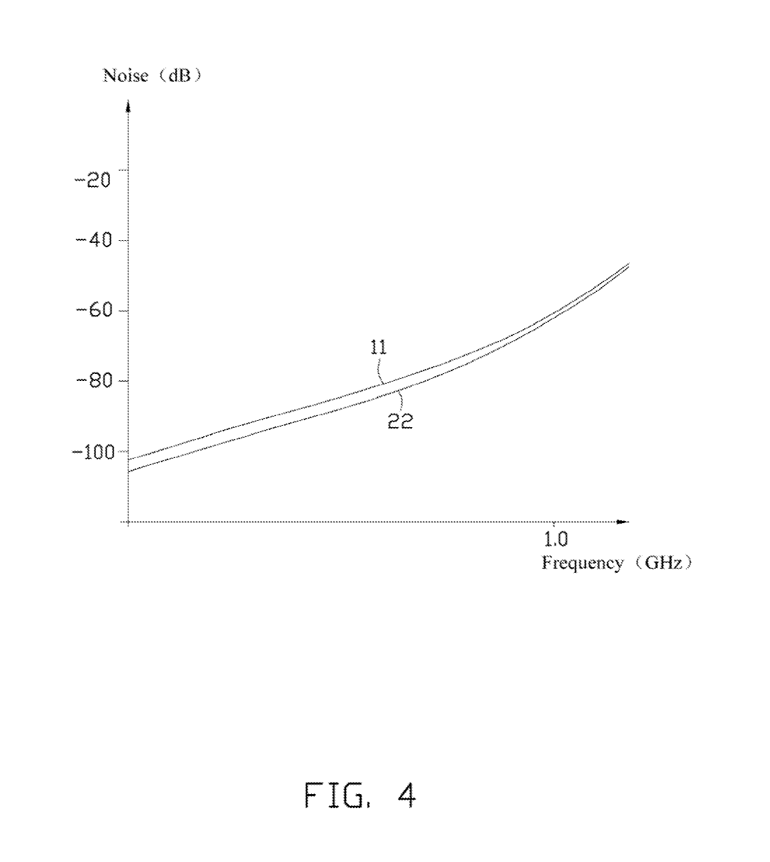

Referring to FIG. 4, two curves are obtained when noise is transmitted to the signal layer 30 under different conditions. A curve 11 is obtained when the through holes 51-55 are not arranged in the PCB 1. A curve 22 is obtained when the through holes 51-55 are arranged in the PCB 1 and located between the power via 70 and the signal line 80. According to FIG. 4, noise with the through holes 51-55 is less than the noise without the holes 51-55 when a 1.0 gigahertz (GHz) voltage signal is transmitted to the signal layer 30.

The PCB 1 can reduce noise transmitted to the signal layers 30, 40, and 60 by arranging the through holes 51-55 between the power via 70 and the signal line 80, to improve quality of signal transmission.

Even though numerous characteristics and advantages of the disclosure have been set forth in the foregoing description, together with details of the structure and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A printed circuit board (PCB), comprising:
a power layer;
a signal layer, wherein a signal line is arranged on the signal layer;
a power via extending through the power layer and the signal layer, and electrically connected to the power layer and the signal layer; and
a plurality of through holes extending through the power layer and the signal layer, and arranged between the signal line and the power via, wherein the plurality of through holes is insulated from the power via, an inside wall of the power via is made of conductive material.

2. The PCB of claim 1, wherein the plurality of through holes is arranged on an arc around the power via.
